(19) United States
(12) Patent Application Publication
(10) Pub. No.: US 2023/0012459 A1
(43) Pub. Date: Jan. 12, 2023

(54) THERMAL CONDUCTIVE DEVICE AND MANUFACTURING METHOD THEREOF, ELECTRICAL CONNECTOR AND ELECTRONIC DEVICE

(71) Applicants: Dongguan Luxshare Technologies Co., Ltd, Dongguan City (CN); Shenzhenshi yeboo industrial CO., LTD, Shenzhen (CN)

(72) Inventors: XiaoKai WANG, Dongguan City (CN); JunZe HU, Dongguan City (CN)

(73) Assignees: Dongguan Luxshare Technologies Co., Ltd, Dongguan City (CN); Shenzhenshi yeboo industrial CO., LTD, Shenzhen (CN)

(21) Appl. No.: 17/512,159

(22) Filed: Oct. 27, 2021

(30) Foreign Application Priority Data
Jul. 8, 2021 (CN) 202110775337.X

(51) Int. Cl. H05K 7/20

(52) U.S. Cl. CPC H05K 7/20427; H05K 7/20436; H01R 13/46

(57) ABSTRACT

A thermal conductive device and thermal conductive device manufacturing method, an electrical connector, and an electronic device. The thermal conductive device comprises first housing, a second housing, a capillary mesh component, and a coolant. The second housing is disposed on the first housing. An airtight and vacuumed accommodating space is provided between the first housing and the second housing. The capillary mesh component is disposed in the accommodating space. The capillary mesh component comprises a plurality of capillary pores. The plurality of capillary pores and the accommodating space form a plurality of interconnected circulation channels. The coolant is filled in the accommodating space. Inside the thermal conductive device, the conventional copper powder sintered configuration is replaced with capillary mesh component, so that the thermal conductive device could be thinned and could present a better thermal conductivity.

### CROSS-REFERENCE TO RELATED APPLICATION

This application claims the priority benefit of Chinese Patent Application Serial Number 202110775337.X, filed on Jul. 8, 2021, the full disclosure of which is incorporated herein by reference.

### BACKGROUND

### Technical Field

The present disclosure relates to the technical field of thermal conductive device, particularly to a thermal conductive device and thermal conductive device manufacturing method, an electrical connector, and an electronic device.

### Related Art

Since electronic devices and connector products generate heat during operation, they are conventionally equipped with thermal conductive devices to conduct generated heat to the outside followed by bringing the heat from the thermal conductive devices through an external cooling device (such as heat sink or cooling fan) so that the thermal conductive device can be continuously conducting heat generated by electronic devices and connector products. Conventional thermal conductivity devices are provided with copper powder sintered internal configuration, which limits the size of the thermal conductive device to make the thermal conductive device unable to be miniaturized for installing in thinned electronic devices and compact size connector products.

### SUMMARY

The embodiments of the present disclosure provide a thermal conductive device and thermal conductive device manufacturing method, an electrical connector, and an electronic device tended to solve the problem that conventional thermal conductive devices could not be thinned due to the size limitation from the copper powder sintered internal configuration therein.

The present disclosure provides a thermal conductive device, comprising a first housing, a second housing, a capillary mesh component, and a coolant. The second housing is disposed on the first housing. An airtight and vacuumed accommodating space is provided between the first housing and the second housing. The capillary mesh component is disposed in the accommodating space. The capillary mesh component comprises a plurality of capillary pores. The plurality of capillary pores and the accommodating space form a plurality of interconnected circulation channels. The coolant is filled in the accommodating space.

The present disclosure further provides a manufacturing method for a thermal conductive device, comprising: providing a first housing with a first liquid injection cover, a second housing with a second liquid injection cover, a capillary mesh component, and a coolant; disposing the capillary mesh component in an accommodating space between the first housing and the second housing; pressing the first housing fit to the second housing, wherein the first liquid injection cover is connected with the second liquid injection cover, and a liquid injection channel communicating with the accommodating space is provided between the first liquid injection cover and the second liquid injection cover; and closing the liquid injection channel to airtight and vacuum the accommodating space.

The present disclosure further provides an electrical connector, comprising a connector housing and a thermal conductive device according to the above aspects. The thermal conductive device is disposed on an outer surface of the connector housing.

The present disclosure further provides an electronic device, comprising a housing accommodating a heating component and a thermal conductive device according to the above aspects. The thermal conductive device is disposed on the housing and corresponds to the heating component.

In the embodiments of the present disclosure, inside the thermal conductive device, by replacing the copper powder sintered configuration with capillary mesh component, the thermal conductive device would be significantly lighter and thinner than conventional ones for meeting the requirements of miniaturization for being installed into thinned and compact electronic devices and electric connectors. Meanwhile, the thermal conductivity of the thermal conductive device of the present disclosure could be reaching or even superior to that of conventional devices.

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a perspective view of a thermal conductive device of the first embodiment of the present disclosure;

FIG. 2 is a cross-sectional view of the thermal conductive device of the first embodiment of the present disclosure;

FIG. 3 is a flow chart of a manufacturing method for the thermal conductive device of the first embodiment of the present disclosure;

FIG. 4 is a schematic diagram of step S12 of the first embodiment of the present disclosure;

FIG. 5 is a cross-sectional view of a thermal conductive wire of the first embodiment of the present disclosure;

FIG. 6 is a flow chart of a manufacturing method for a thermal conductive device of the second embodiment of the present disclosure;

FIG. 7 is a schematic diagram of step S18 of the second embodiment of the present disclosure;

FIG. 8 is a cross-sectional view of a thermal conductive device of the third embodiment of the present disclosure;

FIG. 9 is a cross-sectional view along a length direction of a thermal conductive device of the fourth embodiment of the present disclosure;

FIG. 10 is a cross-sectional view along a width direction of the thermal conductive device of the fourth embodiment of the present disclosure;

FIG. 11 is a cross-sectional view of a thermal conductive device of the fifth embodiment of the present disclosure;

FIG. 12 is a cross-sectional view of a thermal conductive device of the sixth embodiment of the present disclosure;

FIG. 13 is a cross-sectional view of a thermal conductive wire of the seventh embodiment of the present disclosure;

FIG. 14 is a cross-sectional view of a thermal conductive wire of the eighth embodiment of the present disclosure;

FIG. 15 is a perspective view of an electrical connector of the ninth embodiment of the present disclosure; and

FIG. 16 is an exploded view of the electrical connector of the ninth embodiment of the present disclosure.

### DETAILED DESCRIPTION OF THE EMBODIMENTS

The present disclosure will now be described more fully hereinafter with reference to the accompanying drawings, in which exemplary embodiments of the disclosure are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

Certain terms are used throughout the description and following claims to refer to particular components. As one skilled in the art will appreciate, manufacturers may refer to a component by different names. This document does not intend to distinguish between components that differ in name but function. In the following description and in the claims, the terms “include/including” and “comprise/comprising” are used in an open-ended fashion, and thus should be interpreted as “including but not limited to”. “Substantial/substantially” means, within an acceptable error range, the person skilled in the art may solve the technical problem in a certain error range to achieve the basic technical effect.

The following description is of the best-contemplated mode of carrying out the disclosure. This description is made for the purpose of illustration of the general principles of the disclosure and should not be taken in a limiting sense. The scope of the disclosure is best determined by reference to the appended claims.

Moreover, the terms “include”, “contain”, and any variation thereof are intended to cover a non-exclusive inclusion. Therefore, a process, method, object, or device that includes a series of elements not only includes these elements, but also includes other elements not specified expressly, or may include inherent elements of the process, method, object, or device. If no more limitations are made, an element limited by “include a/an . . . ” does not exclude other same elements existing in the process, the method, the article, or the device which includes the element.

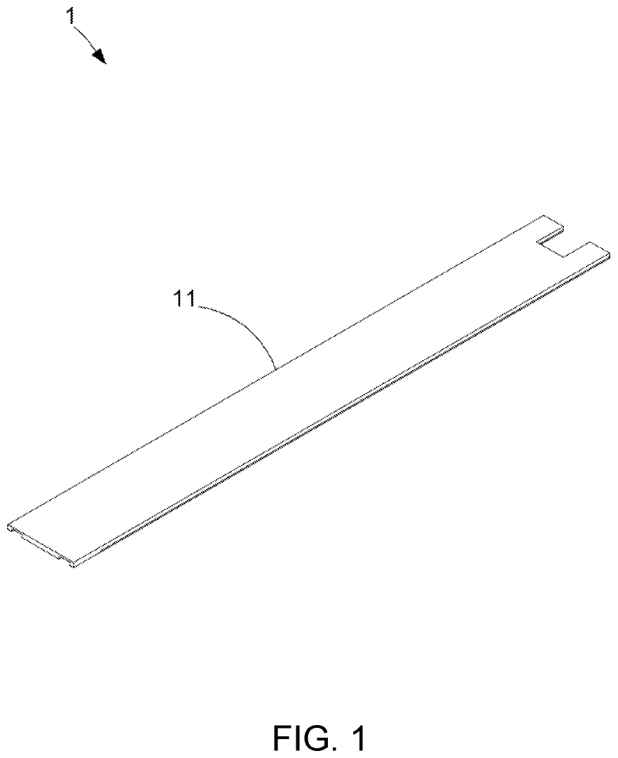

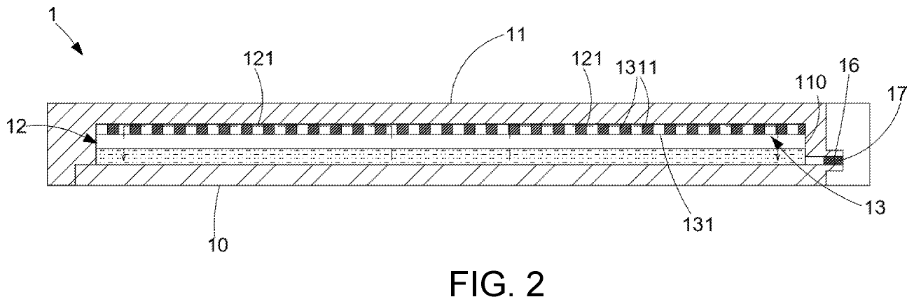

FIG. 1 and FIG. 2 are perspective view and cross-sectional view of a thermal conductive device of the first embodiment of the present disclosure. Since a thermal conductive device 1 of this embodiment is thin, FIG. 0.2 only shows that the size of the thermal conductive device 1 is different from that of the thermal conductive device 1 of FIG. 1 for further descriptions. In this embodiment, the thermal conductive device 1 comprises a first housing 10, a second housing 11, a capillary mesh component 13, and a coolant 14. The second housing 11 is disposed on the first housing 10. An accommodating space 12 is provided between the second housing 11 and the first housing 10. The capillary mesh component 13 is disposed in the accommodating space 12. The capillary mesh component 13 comprises a plurality of capillary pores. The plurality of capillary pores and the accommodating space 12 form a plurality of interconnected circulation channels 121. The coolant 14 is filled in the accommodating space 12.

In this embodiment, when the thermal conductive device 1 is in use, the accommodating space 12 is airtight and vacuumed. The first housing 10 is configured as a heated side, and the second housing 11 is configured as a cooling side. The first housing 10 is heated to cause the coolant 14 to fill in the accommodating space 12 to absorb heat. The heat absorbed coolant 14 is converted to the gas phase of heat-absorbed steam from the liquid phase. The heat-absorbed steam flows to and contacts with the second housing 11, which is the cooling side, thereby the heat-absorbed steam in the gas phase is again condensed into the liquid phase coolant 14. The coolant 14 at the cooling side flows back to the first housing 10, which is the heated side so that the coolant 14 in the thermal conductive device 1 could continuously convert from liquid phase to gas phase then back to liquid phase to perform heat exchange for the purpose of heat conduction. In this embodiment, the first housing 10 could be the heated side, and the second housing 11 could be the cooling side.

In this embodiment, the capillary mesh component 13 comprises only a single layer of the first capillary mesh 131. When the first capillary mesh 131 is in contact with an inner surface of the first housing 10 and is distant from the second housing 11, the first capillary mesh 131 would comprise a plurality of first capillary pores 1311. The plurality of first capillary pores 1311 and the accommodating space 12 form a plurality of interconnected circulation channels, which increase the contact area between the first capillary mesh 131 and the coolant 14. In this way, a large amount of coolant 14 could be converted into heat-absorbed steam considerably, which accelerates the heat absorption and evaporation for the coolant 14. When the first capillary mesh 131 is in contact with an inner surface of the second housing 11 and is distant from the first housing 10, the contact area between the first capillary mesh 131 and the coolant 14 converted from heat-absorbed steam can be increased. In this way, not only can the heat of the heat-absorbed steam be quickly diffused and distributed throughout the second housing 11 to uniform the heat, but external coolings could also bring the heat from on the second housing 11 at a time. Meanwhile, when the heat in a large amount of heat-absorbed steam of the second housing 11 is brought away, a large amount of liquid coolant 14 would be condensed. The large amount of coolant 14 is guided to flow along the inner surface of the second housing 11 toward a sidewall of the accommodating space 12, then along which to flow toward the first housing 10 which is the heated side. The circulation channel refers to when the heat-absorbed steam flows from one side of the accommodating space 12 close to the heated side toward the cooling side, it would pass through the plurality of interconnected first capillary pores 1311 in the first capillary mesh 131 and arrives at the cooling side, and the heat-absorbed steam would be condensed into the coolant 14. The coolant 14 then flows from one side of the accommodating space 12 close to the cooling side toward the heated side and then returns to the heated side through the plurality of interconnected first capillary pores 1311 of the first capillary mesh 131.

Thus, in this embodiment, the heat conduction efficiency of the thermal conductive device 1 can be increased as the first capillary mesh 131 is disposed at any position. The first capillary mesh 131 is in contact with the inner surface of the second housing 11 and is distant from the first housing 10. It is worth mentioning that the first capillary pore 1311 described in this embodiment could also be configured to be circular, rectangular and/or polygonal. Besides, the first capillary mesh 131 can be a fiber type mesh, a woven type mesh, or a honeycomb type mesh.

In this embodiment, the first housing 10 is a flat plate, and the second housing 11 comprises an accommodating groove 110. When the first housing 10 is connected to the second housing 11, a sidewall around the accommodating groove 110 of the second housing 11 would be firmly connected with the inner surface of the first housing 10, and the space within the accommodating groove 110 is referred to as the accommodating space 12. In this embodiment, the first capillary mesh 131 is disposed on an inner surface of the accommodating groove 110. The second housing 11 could also be a flat plate, and the first housing 10 comprises an accommodating groove. Alternatively, the first housing 10 and the second housing 11 could respectively comprise an accommodating groove.

In this embodiment, inside the thermal conductivity device 1 is installed with the capillary mesh component 13 to replace the conventional copper powder sintered configuration so that the thermal conductive device 1 could be significantly lighter and thinner than conventional ones to be miniaturized for being installed into thinned and compact electronic devices and electric connectors. Meanwhile, the thermal conductivity of the thermal conductive device 1 of this embodiment could be reaching or even superior to that of conventional devices.

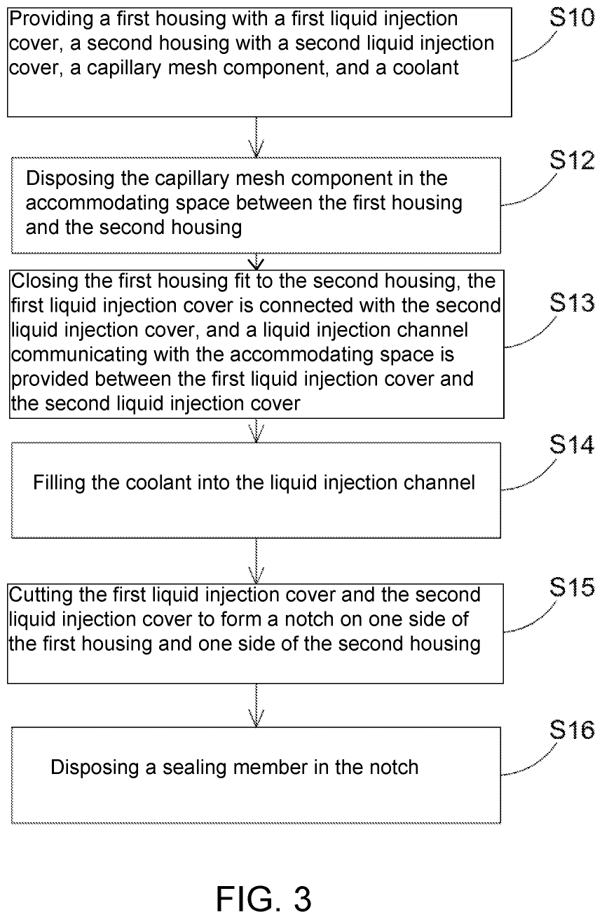

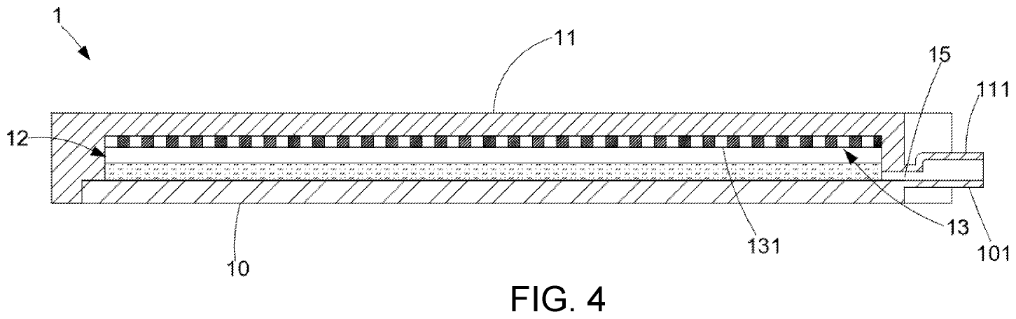

FIG. 3 is a flow chart of a manufacturing method for the thermal conductive device of the first embodiment of the present disclosure. FIG. 4 is a schematic diagram of step S12 of the first embodiment of the present disclosure. As shown in the figures, in this embodiment, the manufacturing steps for the thermal conductive device 1 are performed in order: step S10, a first housing 10 with a first liquid injection cover 101, a second housing 11 with a second liquid injection cover 111, a capillary mesh component 13, and a coolant 14 are provided; step S12, disposing the capillary mesh component 13 in the accommodating space 12 between the first housing 10 and the second housing 11, in this embodiment, the first capillary mesh 131 is disposed in the accommodating space 12 and on the inner surface of the second housing 11; step S13, closing the first housing 10 fit to the second housing 11, wherein the first liquid injection cover 101 is connected with the second liquid injection cover 111, and a liquid injection channel 15 communicating with the accommodating space 12 is provided between the first liquid injection cover 101 and the second liquid injection cover 111, showing that the accommodating space 12 between the first housing 10 and the second housing 11 is not airtight; step S14, filling the coolant 14 into the liquid injection channel 15, then closing the liquid injection channel 15 when the filling is completed to airtight and vacuum the accommodating space 12. Steps S15 and S16 are then performed to close the liquid injection channel 15. In step S15, the first liquid injection cover 101 and the second liquid injection cover 111 are cut to form a notch 16 on one side of the first housing 10 and one side of the second housing 11. In step S16, a sealing member 17 is disposed in the notch 16 to airtight and vacuum the accommodating space 12. The sealing member 17 could also be directly filled into the opening between the first liquid injection cover 101 and the second liquid injection cover 111 without cutting the first liquid injection cover 101 and the second liquid injection cover 111. To cut or not to cut the first liquid filling cover 101 and the second liquid filling cover 111 would depend on the actual situation.

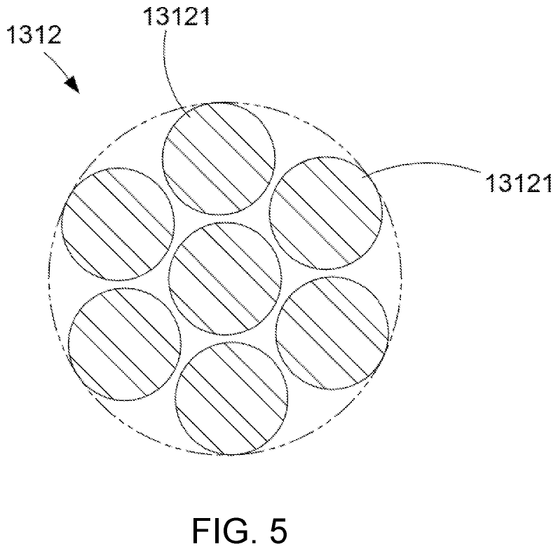

In this embodiment, the first housing 10 and the second housing 11 are respectively manufactured by stamping or etching, which are made of high thermal conductivity materials, such as copper, titanium, aluminum, copper alloy, titanium alloy, aluminum alloy, or stainless steel. Referring to FIG. 5, a cross-sectional view of a thermal conductive wire of the first embodiment of the present disclosure, the first capillary mesh 131 is woven from a plurality of thermal conductive wires 1312, and each of the thermal conductive wires 1312 is woven from a plurality of thermal conductive fibers 13121, which are made of high thermal conductivity materials, such as copper fiber, titanium fiber, or aluminum fiber.

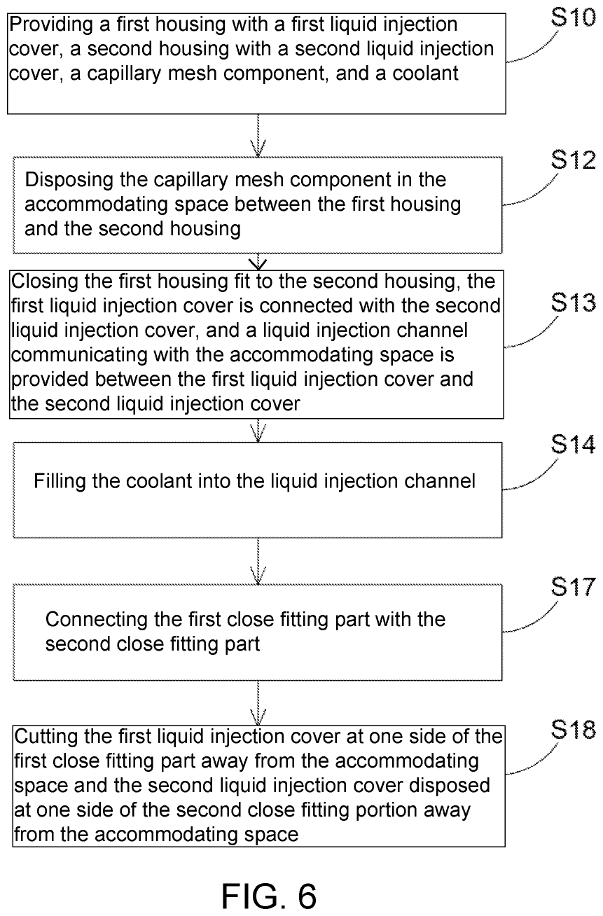

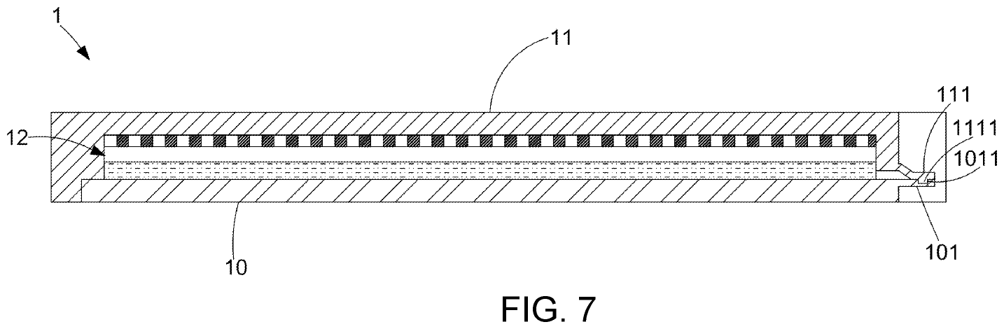

FIG. 6 is a flow chart of a manufacturing method for a thermal conductive device of the second embodiment of the present disclosure. FIG. 7 is a schematic diagram of step S18 of the second embodiment of the present disclosure. As shown in the figures, in this embodiment, the manufacturing method of a thermal conductive device 1 is different from that of the thermal conductive device of the first embodiment in the way of closing the liquid injection channel. In this embodiment, an inner surface of one end of a first liquid injection cover 101 close to an accommodating space 12 is further provided with a first close fitting part 1011, and an inner surface of one end of a second liquid injection cover 111 close to an accommodating space 12 is further provided with a second close fitting part 1111, that is, a notch exists between a first housing 10 and a second housing 11. The inner surface of the first housing 10 at the notch is provided with a first close fitting part 1011, and the inner surface of the second housing 11 at the notch is provided with a second close fitting part 1111. In this embodiment, the first close fitting part 1011 is a recess part, and the second close fitting part 1111 is a bump part. The second close fitting part 1111 can also be a recess part, while the first close fitting part 1011 is still a recess part. When step S14 is completed, go to step S17 to connect the first close fitting part 1011 with the second close fitting part 1111 to airtight and vacuum the accommodating space 12 between the first housing 10 and the second housing 11. Finally, step S18 is performed to cut the first liquid injection cover 101 at one side of the first close fitting part 1011 away from the accommodating space 12 and the second liquid injection cover 111 disposed at one side of the second close fitting part 1111 away from the accommodating space 12. Step S18 of cutting the first liquid injection cover 101 and the second liquid injection cover 111 can be omitted depending on the actual situation.

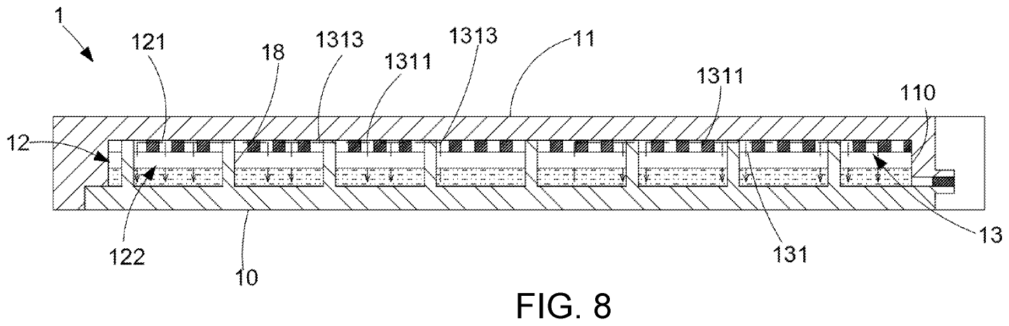

FIG. 8 is a cross-sectional view of a thermal conductive device of the third embodiment of the present disclosure. As shown in the figure, the difference between a thermal conductive device 1 of this embodiment and that of the first embodiment is that a plurality of supporting columns 18 are further provided between a first housing 10 and a second housing 11. The plurality of supporting columns 18 are disposed in an accommodating space 12 at intervals and are configured to support the first housing 10 and the second housing 11 to prevent the first housing 10 and the second housing 11 from being deformed by atmospheric pressure when the thermal conductive device 1 is in use. A plurality of circulation channels 121 of a capillary mesh component 13 are disposed on the plurality of supporting columns 18. Besides, the plurality of supporting columns 18 would partition the accommodating space 12 into a plurality of fluid circulation areas 122 and could guide the flow of heat-absorbed steam or condensed coolant 14 for heat conduction to improve the heat transfer efficiency for each of the fluid circulation areas 122.

In this embodiment, one ends of the plurality of supporting columns 18 are respectively connected with an inner surface of the first housing 10. The other ends of the plurality of supporting columns 18 abutted against an inner surface of the second housing 11. The plurality of supporting columns 18 are integrally formed with the first housing 10. One ends of the plurality of supporting columns 18 can be respectively connected with the inner surface of the second housing 11, the other ends of the plurality of supporting columns 18 can abut against the inner surface of the first housing 10, and the plurality of supporting columns 18 can be integrally formed with the second housing 11. The plurality of supporting columns 18 can be respectively manufactured, for example, by sintering, and can be installed to the first housing 10 or the second housing 11, practically installed to the inner surface of the first housing 10 or the inner surface of the second housing 11 before step S12 of the foregoing manufacturing method. In this embodiment, the supporting column 18 can be a cylindrical column, and it can also be a triangular column, a quadrangular column, and/or a polygonal column, for example, the plurality of supporting columns 18 can all be cylindrical columns or having a combination of being cylindrical column and quadrangular column. The supporting column 18 can be made of high thermal conductivity materials, such as copper, titanium, aluminum, copper alloy, titanium alloy, aluminum alloy, or stainless steel.

In this embodiment, the plurality of supporting columns 18 could penetrate the capillary mesh component 13. In this embodiment, the first capillary mesh 131 comprises a plurality of first through holes 1313. When the first capillary mesh 131 is disposed on the inner surface of the second housing 11 and the second housing 11 is disposed on the first housing 10, the plurality of supporting columns 18 would pass through the plurality of first through holes 1313 of the first capillary mesh 131, so that the plurality of supporting columns 18 would be in contact with the inner surface of the second housing 11.

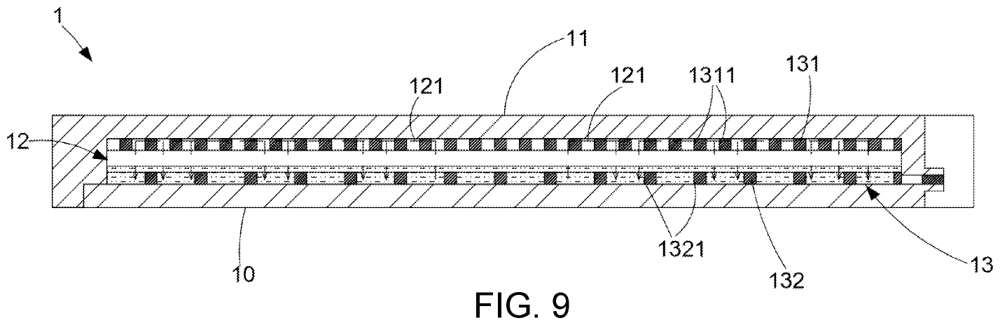

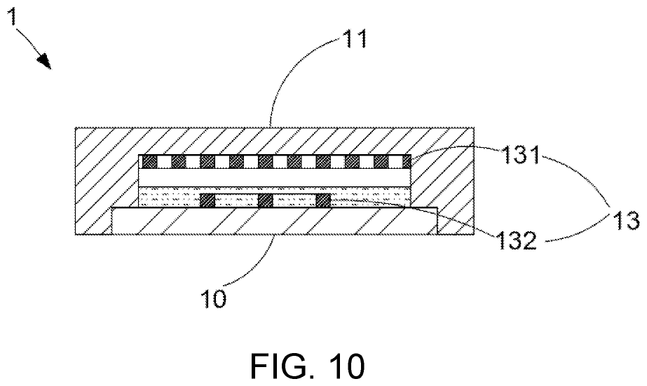

FIG. 9 and FIG. 10 are cross-sectional views along the length direction and width direction of a thermal conductive device of the fourth embodiment of the present disclosure. As shown in the figures, in this embodiment, the difference between the thermal conductive device 1 and that of the first embodiment is that the capillary mesh component 13 of this embodiment having a double-layer capillary mesh. In this embodiment, a capillary mesh component 13 is provided, which comprises a first capillary mesh 131 and a second capillary mesh 132. The first capillary mesh 131 is disposed on an inner surface of a second housing 11, and the second capillary mesh 132 is disposed on an inner surface of the first housing 10. The first capillary mesh 131 is distant from the second capillary mesh 132 and are disposed at intervals. The second capillary mesh 132 comprises a second capillary pore 1321. A plurality of first capillary pores 1311, the plurality of second capillary pores 1321, and an accommodating space 12 form a plurality of circulation channels 121. The manufacturing method of the second capillary mesh 132 is the same as that of the first capillary mesh 131, both of which are woven from a plurality of thermal conductive wires. In this embodiment, the weaving density of the first capillary mesh 131 is greater than the weaving density of the second capillary mesh 132. That is, the size (diameter or width) of the first capillary pore 1311 of the first capillary mesh 131 is smaller than the size (diameter or width) of the second capillary pore 1321 of the second capillary mesh 132, which indicates that the contactable area between the first capillary mesh 131 and the coolant 14 is greater than the contactable area of the second capillary mesh 132 and the coolant 14. In this embodiment, the size (diameter or width) of the first capillary mesh 131 is smaller than the size (diameter or width) of the second capillary mesh 132. In this embodiment, the width of the first capillary mesh 131 is greater than the size of the second capillary mesh 132 (width, length, or area size). In this embodiment, the first capillary mesh 131 covers an inner surface of the accommodating groove of the second housing 11, and the second capillary mesh 132 is only in the middle part of the first housing 10. The size of the first capillary mesh 131 can also be equal to the size of the second capillary mesh 132.

By disposing the second capillary mesh 132 on the first housing 10 to increase the contact area between the second capillary mesh 132 and the coolant 14, a large amount of heat-absorbed coolant 14 can be guided and converted into heat-absorbed steam to speed up the heat-absorbed and vaporizing of the coolant 14. By disposing the first capillary mesh 131 on the second housing 11 to increase the contact area between the first capillary mesh 131 and the heat-absorbed steam and the coolant 14 converted from the heat-absorbed steam. In this way, not only can the heat of the heat-absorbed steam be quickly diffused and distributed throughout the second housing 11 to uniform the heat, but external coolings could also bring the heat from on the second housing 11 at a time. Meanwhile, when the heat of a large amount of heat-absorbed steam of the second housing 11 is brought away, a large amount of liquid coolant 14 would be condensed. The large amount of coolant 14 is guided to flow along an inner surface of the second housing 11 toward a sidewall of the accommodating space 12, then along which to flow toward the first housing 10 which is the heated side. Since the weaving density of the first capillary mesh 131 is lower than that of the second capillary mesh 132, the heat-absorbed steam could be quickly diffused and distributed to the second housing 11, and the condensed coolant 14 could quickly flow back to the first housing 10 which is the heated side. The above is only an embodiment of the present disclosure. The capillary mesh component 13 could include a single layer capillary mesh, a double layer capillary mesh, or a triple or more than three layer capillary mesh. The first capillary mesh 131 and the second capillary mesh 132 could be a fiber type mesh, a woven type mesh, or a honeycomb type meshed, which should not be limited thereto.

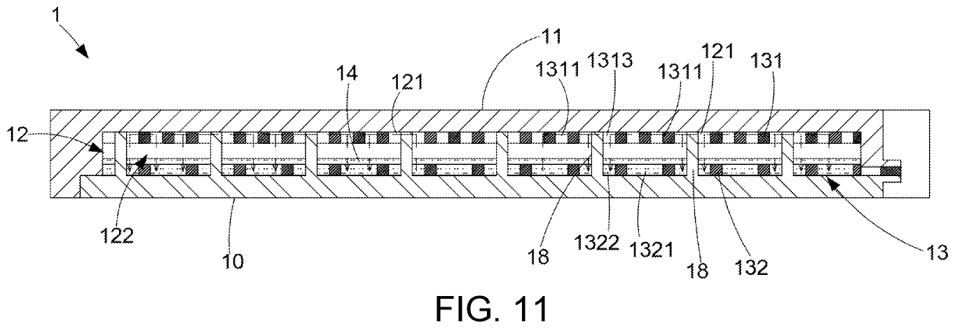

FIG. 11 is a cross-sectional view of a thermal conductive device of the fifth embodiment of the present disclosure. As shown in the figure, a thermal conductive device 1 of this embodiment is different from that of the fourth embodiment in that a plurality of supporting columns 18 are further provided between a first housing 10 and a second housing 11. The plurality of supporting columns 18 are disposed at intervals in an accommodating space 12 and are configured to support the first housing 10 and the second housing 11 to prevent the first housing 10 and the second housing 11 from being deformed by atmospheric pressure when the thermal conductive device 1 is in use. An accommodating space 12 formed by a plurality of first capillary pores 1311 of a first capillary mesh 131, a plurality of second capillary pores 1321 of a second capillary mesh 132, and a plurality of circulation channels 121 is disposed among the plurality of supporting columns 18. Since the configuration of the supporting column 18 of this embodiment is the same as the configuration of the supporting column 18 of the second embodiment, it would not be repeated again. In this embodiment, the plurality of supporting columns 18 respectively penetrate a capillary mesh component 13. The first capillary mesh 131 further comprises a plurality of first through holes 1313, and the second capillary mesh 132 further comprises a plurality of second through holes 1322. When the first capillary mesh 131 and the second capillary mesh 132 are disposed between the first housing 10 and the second housing 11, the plurality of supporting columns 18 would respectively pass through the plurality of first through holes 1313 of the first capillary mesh 131 and the plurality of second through holes 1322 of the second capillary mesh 132 so that the first capillary mesh 131 could be in contact with an inner surface of the second housing 11 and the second capillary mesh 132 could be in contact with an inner surface of the first housing 10.

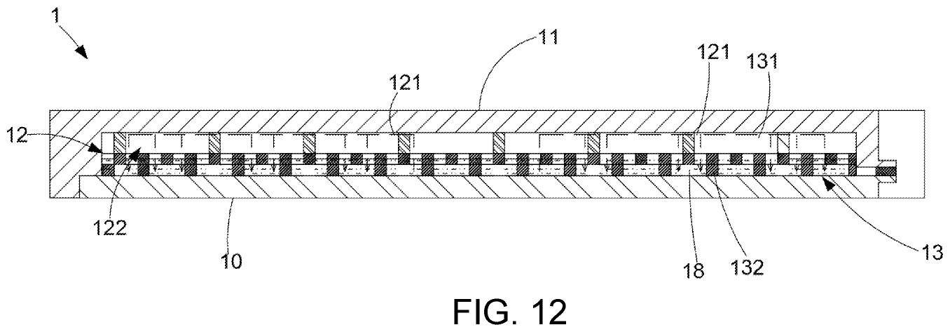

FIG. 12 is a cross-sectional view of a thermal conductive device of the sixth embodiment of the present disclosure. As shown in the figure, the thermal conductive device 1 of this embodiment is different from that of the fifth embodiment in that the plurality of supporting columns 18 do not penetrate the capillary mesh component 13. The plurality of supporting columns 18 abut against the capillary mesh component 13. The first capillary mesh 131 and the second capillary mesh 132 are mutually stacked and are disposed on an inner surface of the first housing 10. One ends of the plurality of supporting columns 18 are connected with an inner surface of a second housing 11, and the other ends of the plurality of supporting columns 18 abut against a surface of the capillary mesh component 13 away from the second housing 11. A plurality of circulation channels 121 of the capillary mesh component 13 are disposed among the plurality of supporting columns 18. The plurality of supporting columns 18 partition the accommodating space 12 into a plurality of fluid circulation areas 122, in which the plurality of circulation channels 121 are disposed in. The plurality of supporting columns 18 could also guide the heat-absorbed steam or condensed coolant 14 to flow and could perform heat conduction for improving the heat conduction efficiency for each of the fluid circulation areas.

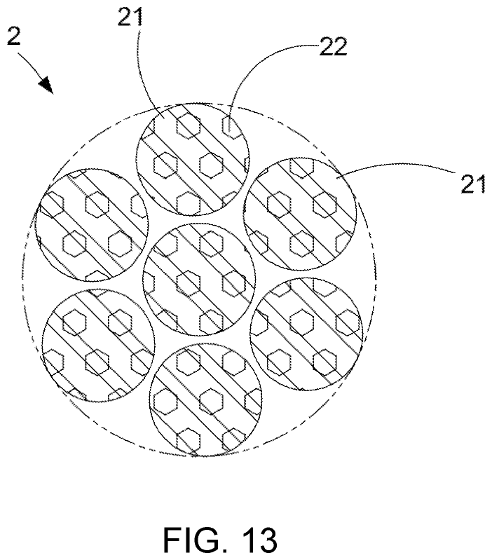

FIG. 13 is a cross-sectional view of a thermal conductive wire of the seventh embodiment of the present disclosure. As shown in the figure, in this embodiment, a thermal conductive wire 2 is provided for weaving capillary mesh. The thermal conductive wire 2 is also woven from a plurality of conductive fibers 21. In this embodiment, a plurality of thermal conductive particles 22 are further added to each of the thermal conductive fibers 21. The materials of the thermal conductive fiber 21 and the thermal conductive particles 22 are highly thermal conductive. In this embodiment, the thermal conductive fiber 21 is a copper fiber, and the thermal conductive particles 22 are copper powder particles, gold powder particles, iron powder particles, etc., which are metal powder particles for heat conduction so that the heat conductivity of the thermal conductive wire 2 can be improved. The capillary mesh of the foregoing embodiments can be woven from the thermal conductive wire 2 of this embodiment so that the thermal conductivity of the capillary mesh can be further improved.

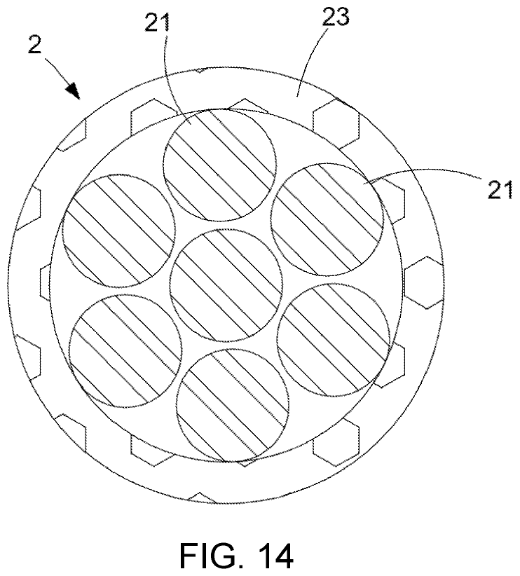

FIG. 14 is a cross-sectional view of a thermal conductive wire of the eighth embodiment of the present disclosure. As shown in the figure, the heat conductive wire 2 of this embodiment is different from that of the seventh embodiment in that an additional heat conductive powder layer 23 is covered on a plurality of woven heat conductive fibers 21, that is, no thermal conductive particle is added. The materials of the thermal conductive fiber 21 and the thermal conductive powder layer 23 are highly thermal conductive. In this embodiment, the thermal conductive fiber 21 is a copper fiber, and the thermal conductive particles 22 are copper powder particles so that the heat conductivity of the thermal conductive wire 2 can be improved. The capillary mesh of the foregoing embodiment can be woven from the thermal conductive wire 2 of this embodiment so that the thermal conductivity of the capillary mesh can be further improved. In this embodiment, the thermal conductive particles of the seventh embodiment can also be added to the plurality of heat conductive fibers 21.

The present disclosure further provides an electronic device, comprising a housing and a thermal conductive device of the above embodiments. The housing accommodates a heating component, and the heat conductive device is disposed at the housing and is connected with the heating component. The thermal conductive device could quickly conduct the heat generated by the heating component of the electronic device to the outside, avoiding the heat from accumulating in the electronic device. A heat sink, a cooling fan, or other heat dissipating components can also be disposed above the thermal conductive device to conduct the heat of the thermal conductive device as soon as possible so that the thermal conductive device could continuously conduct the heat out from the electronic device. In this embodiment, electronic devices refer to those internally installed with heating components, particularly those applied for the field of servers, communications, consumer electronics, and other industries; the electronic devices could be, for example, a data center, server, router, supercomputer, artificial intelligence device, communication station, Intermesh of Things system, game console, laptop, mobile phone, computer, drone, projector, television, medical equipment, robot, inverter, or wind power converter.

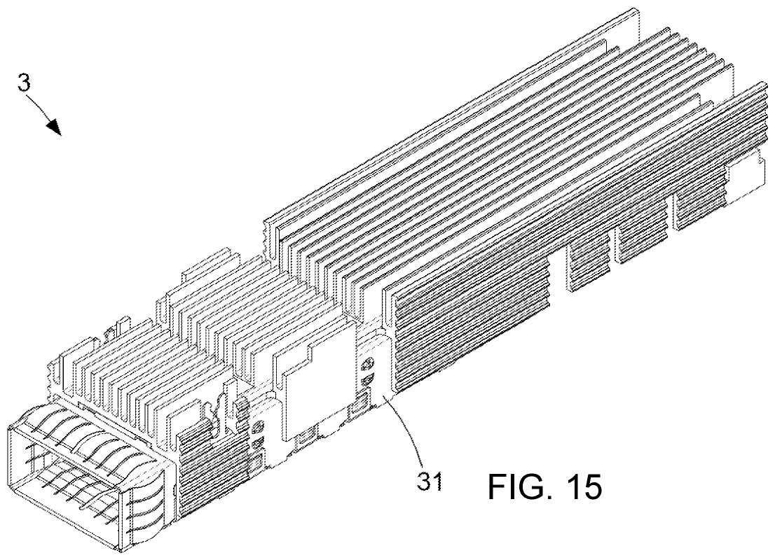

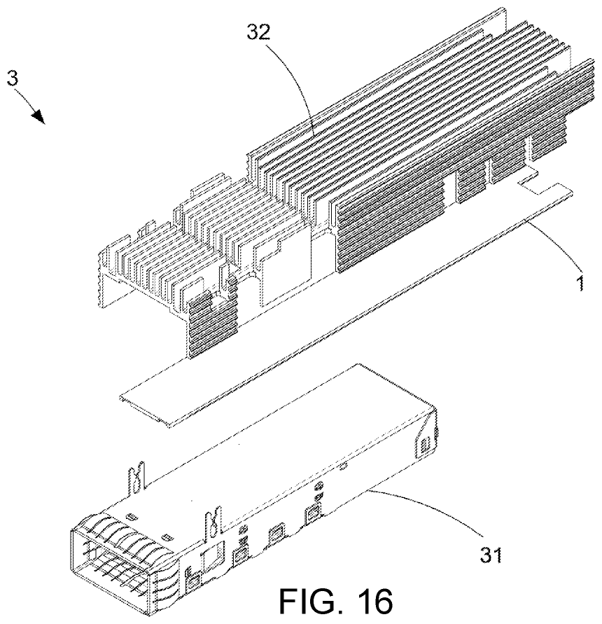

FIG. 15 and FIG. 16 are perspective view and exploded view of an electrical connector of the ninth embodiment of the present disclosure. As shown in the figures, in this embodiment, the electrical connector 3 comprises a connector housing 31 and a thermal conductive device 1. The thermal conductive device 1 is the same as the thermal conductive device of the fifth embodiment and is disposed on an outer surface of the connector housing 31. When the electrical connector 3 is mated with a mating connector, the mating connector would enter the connector housing 31. During signal transmission, the mating connector would generate heat. The thermal conductive device 1 could conduct the heat generated by the mating connector. In this embodiment, the electrical connector 3 further comprises a heat dissipating component 32 disposed on a surface of the thermal conductive device 1 away from the connector housing 31. The heat dissipating component 32 could bring out the heat from the thermal conductive device so that the thermal conductive device could continuously conduct the heat from the electronic device. In this embodiment, the heat dissipating component 32 is a fin type heat sink.

In summary, embodiments of the present disclosure provide a thermal conductive device and thermal conductive device manufacturing method, an electrical connector, and an electronic device. Inside the thermal conductive device, by replacing the copper powder sintered configuration with a capillary mesh component, the thermal conductive device would be significantly lighter and thinner than conventional ones for meeting the requirements of miniaturization for being installed into thinned and compact electronic devices and electric connectors. Meanwhile, the thermal conductivity of the thermal conductive device of the present disclosure could be reaching or even superior to that of conventional devices.

It is to be understood that the term “comprises”, “comprising”, or any other variants thereof, is intended to encompass a non-exclusive inclusion, such that a process, method, article, or device of a series of elements not only comprise those elements but further comprises other elements that are not explicitly listed, or elements that are inherent to such a process, method, article, or device. An element defined by the phrase “comprising a . . . ” does not exclude the presence of the same element in the process, method, article, or device that comprises the element.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the disclosure. Accordingly, such modifications are considered within the scope of the disclosure as limited solely by the appended claims.

What is claimed is:

1. A thermal conductive device, comprising:
a first housing;
a second housing disposed on the first housing, an airtight and vacuumed accommodating space being provided between the first housing and the second housing;
a capillary mesh component disposed in the accommodating space, comprising a plurality of capillary pores, the plurality of capillary pores and the accommodating space forming a plurality of interconnected circulation channels; and
a coolant filled in the accommodating space.

2. The thermal conductive device according to claim 1, wherein the capillary mesh component comprises a first capillary mesh disposed on an inner surface of the second housing; a gap exists between the first capillary mesh and the inner surface of the first housing; or the first capillary mesh is disposed on an inner surface of the first housing; a gap exists between the first capillary mesh and the inner surface of the second housing.

3. The thermal conductive device according to claim 2, wherein the first capillary mesh is woven from a plurality of thermal conductive wires.

4. The thermal conductive device according to claim 1, wherein the capillary mesh component comprises a first capillary mesh and a second capillary mesh; the first capillary mesh is disposed on an inner surface of the second housing; the second capillary mesh is disposed on an inner surface of the first housing.

5. The thermal conductive device according to claim 4, wherein a gap exists between the first capillary mesh and the second capillary mesh; the first capillary mesh and the second capillary mesh are disposed at intervals.

6. The thermal conductive device according to claim 4, wherein the first capillary mesh and the second capillary mesh are respectively woven from a plurality of thermal conductive wires; the weaving density of the first capillary mesh is greater than the weaving density of the second capillary mesh.

7. The thermal conductive device according to claim 6, wherein the plurality of thermal conductive wires are respectively woven from a plurality of thermal conductive fibers.

8. The thermal conductive device according to claim 7, wherein inside the plurality of thermal conductive fibers is further provided with a plurality of thermal conductive particles.

9. The thermal conductive device according to claim 7, wherein the plurality of thermal conductive wires respectively comprise a thermal conductive powder layer covering the plurality of thermal conductive fibers.

10. The thermal conductive device according to claim 1, wherein a plurality of supporting columns are further provided between the first housing and the second housing; the plurality of supporting columns penetrate the capillary mesh component; one ends of the plurality of supporting columns are connected with an inner surface of the first housing; the other ends of the plurality of supporting columns abut against an inner surface of the second housing; or, one ends of the plurality of supporting columns are connected with the inner surface of the second housing; the other ends of the plurality of supporting columns abut against the inner surface of the first housing; the plurality of circulation channels are disposed between the plurality of support columns.

11. The thermal conductive device according to claim 1, wherein a plurality of supporting columns are further provided between the first housing and the second housing; one ends of the plurality of supporting columns are connected with an inner surface of the first housing; the plurality of supporting columns press the capillary mesh component on an inner surface of the second housing; or, one ends of the plurality of supporting columns are connected with the inner surface of the second housing; the plurality of supporting columns press the capillary mesh component on the inner surface of the first housing; the plurality of circulation channels are disposed between the plurality of support columns.

12. The thermal conductive device according to claim 11, wherein the plurality of supporting columns and the first housing are integrally formed; or, the plurality of supporting columns and the second housing are integrally formed.

13. The thermal conductive device according to claim 11, wherein the plurality of supporting columns are respectively cylindrical, triangular, quadrangular, and/or polygonal.

14. A manufacturing method for a thermal conductive device, comprising:
providing a first housing with a first liquid injection cover, a second housing with a second liquid injection cover, a capillary mesh component, and a coolant;
disposing the capillary mesh component in an accommodating space between the first housing and the second housing;
pressing the first housing fit to the second housing, the first liquid injection cover being connected with the second liquid injection cover, a liquid injection channel communicating with the accommodating space provided between the first liquid injection cover and the second liquid injection cover; and
closing the liquid injection channel to airtight and vacuum the accommodating space.

15. The manufacturing method for a thermal conductive device according to claim 14, wherein the step of closing the liquid injection channel comprises:
cutting the first liquid injection cover and the second liquid injection cover to form a notch on one side of the first housing and the second housing; and
disposing a sealing member in the notch.

16. The manufacturing method for a thermal conductive device according to claim 14, wherein the step of closing the liquid injection channel comprises:
connecting the first close fitting part of the first liquid filling cover and the second close fitting part of the second liquid filling cover; and
cutting the first liquid injection cover disposed at one side of the first close fitting part away from the accommodating space and the second liquid injection cover disposed at one side of the second close fitting part away from the accommodating space.

17. The manufacturing method for a thermal conductive device according to claim 14, wherein the capillary mesh component comprises at least one capillary mesh; the at least one capillary mesh is woven from a plurality of thermal conductive wires; the plurality of thermal conductive wires are respectively woven from a plurality of thermal conductive fibers; the plurality of thermal conductive fibers is made of copper fiber, titanium fiber, or aluminum fiber.

18. The manufacturing method for a thermal conductive device according to claim 17, wherein inside the plurality of thermal conductive fibers of the thermal conductive wire is provided with a plurality of thermal conductive particles; and/or an outer side of the plurality of thermal conductive fibers are covered with a thermal conductive powder layer.

19. An electrical connector, comprising:
a connector housing; and
a thermal conductive device according to claim 1, disposed on an outer surface of the connector housing.

20. An electronic device, comprising:
a housing accommodating a heating component; and
a thermal conductive device according to claim 1, disposed on the housing and corresponding to the heating component.
